(19) United States
(12) Patent Application Publication
(10) Pub. No.: US 2013/0199440 A1
(43) Pub. Date: Aug. 8, 2013

(54) MONOCRYSTALLINE SEMICONDUCTOR MATERIALS

(71) Applicants: Uwe Kerat, Baiersbronn (DE); Christian Schmid, Freudenstadt (DE); Jochem Hahn, Rottenburg a. N. (DE)

(72) Inventors: Uwe Kerat, Baiersbronn (DE); Christian Schmid, Freudenstadt (DE); Jochem Hahn, Rottenburg a. N. (DE)

(73) Assignee: SCHMID SILICON TECHNOLOGY GMBH, Freudenstadt (DE)

(21) Appl. No.: 13/639,170

(22) PCT Filed: Apr. 11, 2011
(86) PCT No.: PCT/EP11/55626

§ 371 Date: Nov. 21, 2012

(30) Foreign Application Priority Data
Apr. 13, 2010 (DE) 10 2010 015 354.0
May 14, 2010 (DE) 10 2010 021 004.8

(51) Int. Cl. C30B 11/00

(52) U.S. Cl. CPC C30B 11/003; C30B 11/005
USPC 117/83; 117/223

(57) ABSTRACT

A method of producing a monocrystalline semiconductor material includes providing a starting material composed of the semiconductor material, transferring the starting material into a heating zone in which a melt composed of the semiconductor material is fed with the starting material, and lowering the melt from the heating zone and/or raising the heating zone such that, at a lower end portion of the melt, a solidification front forms along which the semiconductor material crystallizes in a desired structure, wherein the starting material composed of the semiconductor material is provided in liquid form and fed into the melt in liquid form.

### RELATED APPLICATIONS

This is a §371 of International Application No. PCT/EP2011/055626, with an inter-national filing date of Apr. 11, 2011 (WO 2011/128292 A1, published Oct. 20, 2011), which is based on German Patent Application Nos. 10 2010 015 354.0, filed Apr. 13, 2010, and 10 2010 021 004.8, filed May 14, 2010, the subject matter of which is incorporated by reference.

### TECHNICAL FIELD

This disclosure relates to a method for producing monocrystalline semiconductor materials, in particular monocrystalline silicon. Furthermore, the disclosure relates to an installation for producing such monocrystalline semiconductor materials.

### BACKGROUND

Elemental silicon is used in different degrees of purity inter alia in photovoltaics (solar cells) and in microelectronics (semiconductors, computer chips). Accordingly, it is customary to classify elemental silicon on the basis of its degree of purity. A distinction is made between, for example, “electronic grade silicon” having a proportion of impurities in the PPT range and “solar grade silicon,” which is permitted to have a somewhat higher proportion of impurities.

In the production of solar grade silicon and electronic grade silicon, metallurgical silicon (in general 98-99% purity) is always taken as a basis and is purified by a multistage, complex method. Thus, it is possible, for example, to convert the metallurgical silicon to trichlorosilane in a fluidized bed reactor using hydrogen chloride, the trichlorosilane subsequently being disproportionated to form silicon tetrachloride and monosilane. The latter can be thermally decomposed into its elemental constituents silicon and hydrogen. A corresponding method sequence is described in WO 2009/121558, for example.

The obtained silicon quite generally has at least a sufficiently high purity to be classified as solar grade silicon. Even higher purities can be obtained, if appropriate, by downstream additional purification steps. At the same time, for many applications it is favourable or even necessary for the silicon which emerges from the above method and is generally obtained in polycrystalline form to be converted into monocrystalline silicon. Thus, solar cells composed of monocrystalline silicon have a generally significantly higher efficiency than solar cells composed of polycrystalline silicon.

Conversion of polycrystalline silicon into monocrystalline silicon is generally effected by melting the polycrystalline silicon and subsequent crystallization in a monocrystalline structure with the aid of a seed crystal.

One technique for producing monocrystalline silicon which makes it possible to produce silicon single crystals having a particularly high degree of purity is the so-called “float zone” method (FZ), which was first proposed by Keck and Golay. An example of an FZ method and a device suitable for such a method are presented, e.g., in EP 1595006 B1.

The FZ technique affords some significant advantages over alternative methods such as the known Czochralski method, for example, in particular as far as the purity of the monocrystalline silicon obtained is concerned. This is because in an FZ method the silicon melt used for crystal growth is not held in a crucible. Instead, the lower end of a rod composed of polysilicon is lowered into the heating region of an induction heating system and carefully melted. A melt composed of molten silicon accumulates below the silicon rod, a seed crystal composed of monocrystalline silicon being dipped into the melt, generally from below. As soon as the seed crystal is wetted with the silicon melt, the crystal growth can be started by the silicon melt being slowly lowered from the heating zone. The silicon rod to be melted must be repositioned from above at the same time such that the volume of the melt remains substantially constant. In the course of lowering the melt, at the underside thereof a solidification front forms along which the liquid silicon crystallizes in the desired structure.

Production of monocrystalline silicon proceeding from metallurgical silicon involves a very high expenditure of energy. It is characterized by a complex sequence of chemical processes and changes in state of matter. In this connection, reference is made, for example, to WO 2009/121558 mentioned above. The silicon obtained in the multistage process described therein is obtained in a pyrolysis reactor in the form of solid rods which, if appropriate, have to be comminuted and melted again for subsequent further processing, for example, in a Czochralski method or an FZ method.

It could therefore be helpful to provide a new technique for producing monocrystalline silicon which is distinguished, in particular, by a simplified method sequence and also by energetic optimization relative to known method sequences.

### SUMMARY

We provide a method of producing a monocrystalline semiconductor material including providing a starting material composed of the semiconductor material, transferring the starting material into a heating zone in which a melt composed of the semiconductor material is fed with the starting material, and lowering the melt from the heating zone and/or raising the heating zone such that, at a lower end portion of the melt, a solidification front forms along which the semiconductor material crystallizes in a desired structure, wherein the starting material composed of the semiconductor material is provided in liquid form and fed into the melt in liquid form.

We also provide an installation that produces a monocrystalline semiconductor material including a source of a liquid semiconductor material serving as starting material, heating media that produce and/or maintain a melt composed of the semiconductor material, and media for the controlled feeding of the liquid semiconductor material serving as starting material into the melt.

### BRIEF DESCRIPTION OF THE DRAWING

FIG. 1 shows a schematic illustration of an example of an installation which produces a monocrystalline semiconductor material.

### DETAILED DESCRIPTION

We provide a method that obtains a wide variety of semiconductor materials in monocrystalline form. In particular, the method is suitable for producing monocrystalline silicon. In this case, it always comprises at least the following steps:
1. In one step, a semiconductor material is provided as starting material. The semiconductor material is preferably silicon.
2. In a further step, the starting material is transferred into a heating zone. A melt composed of the semiconductor material is situated in the heating zone, the melt being fed with starting material. The melt is a “freely floating melt” as in traditional FZ methods, e.g., the method described in EP 1595006 B1. This should be understood to mean a melt which is not in contact with the walls of a vessel such as a crucible. Instead, its stability is maintained in a contactless manner, which will be discussed in greater detail below.
3. By lowering the melt from the heating zone or alternatively by raising the heating zone, it is possible to bring about formation of a solidification front at the lower end of the melt, along which the semiconductor material solidifies in the desired monocrystalline structure. Lowering the melt from the heating zone and the abovementioned raising of the heating zone can also be effected simultaneously.

The method is particularly distinguished by the fact that the starting material composed of the semiconductor material is provided in liquid form and also fed into the melt in liquid form.

The method thus has some commonalities with traditional FZ methods, in particular the “freely floating melt” mentioned. Maintenance and stabilization of the melt and also cooling the melt, in particular by lowering the melt from the heating region, can be effected in accordance with known procedures such as mentioned and described, e.g., in EP 1595006 B1. In contrast to traditional FZ methods, however, the melt is not fed by repositioning a solid semiconductor material, in particular a solid silicon rod as mentioned in the introduction. Instead, the melt is fed with starting material which is not first melted directly above the melt, but rather is already in liquefied form.

To form the desired monocrystalline structure, the melt is seeded preferably with a seed composed of a monocrystalline semiconductor material, in particular a seed composed of monocrystalline silicon, which can be dipped into the melt, in particular from below. The melt correspondingly solidifies during cooling along the solidification front at its lower end in a monocrystalline structure.

The as yet unpublished DE 102010011853.2 and WO 2010/060630 (PCT/EP2009/008457) each describe methods for obtaining silicon wherein silicon is obtained in liquid form. The subject matter of PCT/EP2009/008457 is hereby incorporated by reference.

To provide the liquid starting material, preferably, particles of the semiconductor material and/or a precursor compound of the semiconductor material are fed into a gas flow, as described in DE '853.2 and WO '630. If appropriate, both particles of the semiconductor material and a precursor compound of the semiconductor material can be fed into the gas flow. The gas flow has a sufficiently high temperature to convert the particles of the semiconductor material from the solid to the liquid and/or gaseous state and/or to thermally decompose the precursor compound.

The precursor compound of the semiconductor material can also be heated directly such that thermal decomposition of the precursor compound occurs, for example, by energy being fed thereto by electrostatic or electromagnetic fields to convert it into a plasma-like state. Preferably, however, it is fed into a highly heated gas flow for the purpose of decomposition.

The particles of the semiconductor material are, in particular, metallic silicon particles such as can be obtained in large amounts, for example, when silicon blocks are sawed to form thin wafer slices composed of silicon. Under certain circumstances, the particles can be at least slightly oxidized superficially.

The precursor compound of the semiconductor material is preferably a silicon-hydrogen compound, particularly preferably monosilane (SiH₄). However, the use of other silicon-containing compounds, in particular chlorosilanes such as, for example, trichlorosilane (SiHCl₃), in particular, is also possible by way of example.

The gas flow into which the particles of the semiconductor material and/or the precursor compound of the semiconductor material are fed generally comprises at least one carrier gas. Preferably, it consists of such a carrier gas. The proportion made up by the precursor compound of the semiconductor material in the mixture with the at least one carrier gas is particularly preferably 5% by weight to 99% by weight, in particular 5% by weight to 50% by weight, particularly preferably 5% by weight to 20% by weight. An appropriate carrier gas is hydrogen, in particular, which is advantageous particularly when the precursor compound is a silicon-hydrogen compound. Further preferably, the carrier gas can also be a carrier gas mixture, for example, composed of hydrogen and a noble gas, in particular argon. The noble gas is then contained in the carrier gas mixture preferably in a proportion of between 1% and 50%.

The gas flow preferably has a temperature of 500° C. to 5000° C., particularly preferably 1000° C. to 5000° C., in particular 2000° C. to 4000° C. At such a temperature, first, e.g., particles of silicon can be liquefied or even at least partly evaporated in the gas flow. Silicon-hydrogen compounds and other conceivable precursor compounds of the semiconductor material are also generally readily decomposed into their elemental constituents at such temperatures.

Particularly preferably, the gas flow is a plasma, in particular a hydrogen plasma. As is known, a plasma is a partly ionized gas containing an appreciable proportion of free charge carriers such as ions or electrons. A plasma is always obtained by external energy supply, which can be effected, in particular, by thermal excitation, irradiation excitation or by excitation by electrostatic or electromagnetic fields. The latter excitation method, in particular, is preferred. Corresponding plasma generators are commercially available and need not be explained in greater detail.

After the process of feeding the particles of the semiconductor material and/or the precursor compound of the semiconductor material into the gas flow, it is necessary to condense out (if necessary) resulting gaseous semiconductor material from the gas flow and also to separate the resulting gaseous and/or liquid semiconductor material, if appropriate, from the carrier gas component. For this purpose, preferably, use is made of a reactor container into which the gas flow with the particles of the semiconductor material and/or the precursor compound of the semiconductor material or with corresponding gaseous and/or liquid subsequent products composed thereof is introduced. Such a reactor container serves to collect and, if appropriate, condense the liquid and/or gaseous semiconductor material. In particular, it is provided to separate the mixture of carrier gas, semiconductor material (liquid and/or gaseous) and, if appropriate, gaseous decomposition products, the mixture arising in preferred examples of our method.

The liquid starting material thus obtained is preferably fed into the melt composed of the semiconductor material directly from the reactor container. Alternatively, however, the liquid starting material can also be transferred into a collecting container having high thermal stability after the condensation or separation from the gas flow, in which collecting container the material can be temporarily stored. The melt composed of the semiconductor material can also be fed from the collecting container.

As already mentioned in the introduction, a major advantage of the FZ technique is that, for example, liquid silicon, during crystallization, does not come into contact with the walls of a crucible, as is the case in the Czochralski method, for example. Even if the crucible walls are produced from material having very high thermal stability such as, e.g., quartz, impurity elements such as oxygen can diffuse from the reactor walls into the liquid silicon and influence the properties thereof, at least if there is contact with the liquid silicon over a relatively long period of time. Diffusion of impurity atoms into liquid semiconductor materials such as liquid silicon would, of course, are possible proceeding from walls of the abovementioned reactor container and/or of the abovementioned collecting container. It is correspondingly desirable if the liquid semiconductor material also not directly contact with the walls, or at least not over a relatively long time.

Preferably, the reactor container and/or the collecting container are therefore coated internally with a solid layer (also designated as “skull”) composed of the solidified semiconductor material. This holds true, in particular, for regions of the inner walls which can directly contact the liquid semiconductor material, that is to say, for example, for the bottom regions of the container in which, if appropriate, e.g., liquid silicon that has condensed out accumulates. The solid layer composed of the solidified semiconductor material shields the container walls from liquid semiconductor material (or vice versa), and permanent diffusion of impurities into the liquid semiconductor material is thereby prevented.

The thickness of the layer composed of the solidified semiconductor material is preferably monitored by a sensor. This can be very important since the layer should ideally have a certain minimum thickness, but at the same time not grow in an uncontrolled manner. It is correspondingly necessary to maintain a thermal equilibrium within the container, in particular in the region of the container walls. For this purpose it is possible to provide, in particular within the walls, heating and/or cooling media, which are ideally coupled to the abovementioned sensor by a controller to be able to counteract possible fluctuations in the thickness by corresponding measures. Ultrasonic sensors, in particular, are suitable as the sensor. It is also conceivable to carry out conductivity measurements.

Preferably, the reactor container and/or the collecting container have a bottom region which at least partly consists of the semiconductor material to be produced, in particular high-purity silicon. In particular, it is also possible for the reactor container and/or the collecting container to have in the bottom region an outlet for liquid semiconductor material, the outlet being blocked by a plug composed of the solidified semiconductor material. Preferably, to feed the liquid semiconductor material into the melt, the bottom region which at least partly consists of the semiconductor material to be produced, in particular the “plug” composed of the solidified semiconductor material which blocks the abovementioned outlet, is melted in a controlled manner. In this way, it is possible to control the amount of liquid semiconductor material which is fed into the melt.

To keep the melt itself stable, it is necessary not to feed too much liquid semiconductor material to the melt. Therefore, control of the amount of semiconductor material fed into the melt is very important. This is because the hydrostatic pressure in the melt is directly proportional to the height thereof. The latter should therefore always be kept in a certain, very narrowly stipulated range. The volume of the melt should therefore remain substantially constant. The amount of liquid semiconductor material fed should be no more than simultaneously solidifies at the lower end of the melt.

Alternatively or additionally, the amount of liquid semiconductor material fed into the melt can, of course, also be controlled by correspondingly metering the amount of particles of the semiconductor material and/or the precursor compound of the semiconductor material which are fed into the abovementioned highly heated gas flow. The amount, e.g., of the precursor compound which is fed into the gas flow can be metered very finely. It is thus possible to produce continuously precisely definable amounts of liquid semiconductor material. To maintain the melting zone stability, this procedure can be highly advantageous and, moreover, complex control of the outflow of the liquid semiconductor material from the reactor container is thus not absolutely necessary.

The of the bottom region which at least partly consists of high-purity semiconductor material is preferably controlled by heating and/or cooling media arranged in the bottom region of the reactor container or at least assigned thereto. In this case, the heating and/or cooling media preferably comprise at least one induction heating system with which the bottom region of the reactor container and/or of the collecting container can be heated. Preferably, the cooling media are integrated into the bottom region of the reactor container and/or of the collecting container, in particular arranged around the abovementioned outlet for liquid semiconductor material.

Furthermore, particularly preferably, the heating and/or cooling media can also comprise at least one focusable light beam and/or beam of matter, in particular in addition, but if appropriate also as an alternative to the at least one induction heating system mentioned. Such a focusable light beam and/or beam of matter can be, in particular, a laser or an electron beam. By this locally delimited manner, e.g., partial regions of the bottom region of the reactor container and/or of the collecting container which consist of the semiconductor material to be produced or the blocking plug composed of solidified semiconductor material can be liquefied in a targeted manner such that an outlet is opened, via which liquid semiconductor material can exit. By varying the intensity and focusing of the light beam and/or beam of matter, it is possible to influence the size of the liquefied region. An uncontrolled exit of liquid silicon can thus be avoided.

The heating zone in which the melt composed of the semiconductor material is arranged also comprises preferably at least one heating medium which can be, in particular, an induction heating system and/or a focusable light beam and/or beam of matter. Preferably, one and the same heating medium, in particular one and the same induction heating system, can serve both to maintain the melt in the heating zone and to heat the bottom region of the reactor container and/or of the collecting container.

The method can be carried out in all installations comprising a source of a liquid semiconductor material serving as starting material, a heating medium for producing and/or maintaining a freely floating melt composed of a semiconductor material, the melt arranged in a heating region, media for lowering the melt from the heating region and/or media for raising the heating region and preferably also media for the controlled feeding of the liquid semiconductor material serving as starting material into the melt.

The source of the liquid semiconductor material serving as starting material is preferably the abovementioned reactor container and/or the abovementioned collecting container for liquid silicon. These generally comprise a heat-resistant interior. So that the latter (in particular in the case of the reactor container) is not destroyed by the above-described highly heated gas flow, it is generally lined with corresponding materials having high thermal stability. By way of example, linings based on graphite or silicon nitride are suitable. Suitable materials resistant to high temperatures are known.

Within the reactor container, in particular the question of the transition of vapors formed, if appropriate such as silicon vapors, into the liquid phase is of great importance. Of course, the temperature of the inner walls of the reactor is an important factor for this. It is preferably in the region of the melting point of silicon, but in any case below the boiling point of silicon. Preferably, the temperature of the walls is kept at a relatively low level, in particular just below the melting point of silicon. This holds true in particular when a layer composed of solidified semiconductor material, in particular composed of solidified silicon, is intended to be formed on the inside of the reactor container, as described above. To set the temperatures required for this purpose, the reactor container can have suitable insulating, heating and/or cooling media.

Liquid semiconductor material should be able to accumulate at the bottom of the reactor. For this purpose, the bottom of the interior of the reactor can be a conical shape with an outflow at the deepest point to facilitate discharge of the liquid semiconductor material. The reactor container has, for the controlled discharge of the liquid semiconductor material, for example, the already described bottom region which at least partly consists of the semiconductor material to be produced, in particular the outlet for liquid semiconductor material which is blocked by a plug composed of the solidified semiconductor material. The outlet or the bottom region can be assigned an additional blocking medium by which it is possible to prevent liquid semiconductor material from flowing out of the reactor in an uncontrolled manner. The blocking medium preferably consists of a material which cannot be heated by high-frequency induction or is heated thereby at least not as successfully as silicon. Preference is given, in particular, to materials having a higher melting point than silicon. The blocking medium can be, for example, a plate or a slide which can be used to close off, e.g., the outlet for the liquid semiconductor material.

Furthermore, of course, the gas introduced into the reactor container or the gas formed there, if appropriate, by decomposition also has to be discharged again. Besides a supply line for the gas flow, a corresponding gas discharge line is generally provided for this purpose.

The gas flow is preferably introduced into the reactor container at relatively high speeds to ensure good swirling within the reactor container. Preferably, a pressure slightly above standard pressure, in particular 1013 to 2000 Millibar (mbar), prevails in the reactor container.

Preferably, at least one section of the interior of the reactor is substantially cylindrical. The gas flow can be introduced via a channel leading into the interior. The opening of this channel is arranged particularly in the upper region of the interior, preferably at the upper end of the substantially cylindrical section.

The media for the controlled feeding of the liquid semiconductor material serving as starting material into the melt are preferably grooves and/or pipes. The liquid semiconductor material can thus be transferred from the reactor container into the heating region, if appropriate on a detour via a collecting container. The grooves and/or pipes can be produced from quartz, from graphite or from silicon nitride, for example. If appropriate, heating units can be assigned to these media to prevent the liquid semiconductor material from solidifying during transport. Preferably, the media can also be coated with a solid layer composed of the solidified semiconductor material in the regions which come into contact with the liquid semiconductor material, as is also the case in the reactor container described above. For this purpose, too, the installation can comprise suitable heating and/or cooling media.

Furthermore, the media for the controlled feeding of the liquid semiconductor material serving as starting material into the melt can also comprise the heating and/or cooling media already described above with which the melting of the bottom region which at least partly consists of high-purity semiconductor material is controlled. In particular, they can comprise in combination an induction heating system serving to maintain the freely floating melt and also heat the bottom region of the reactor container and simultaneously at least one focusable light beam and/or beam of matter with the aid of which—in a locally delimited manner—partial regions of the bottom region of the reactor container and/or of the collecting container which consist of the semiconductor material can be liquefied in a targeted manner.

As already mentioned above, liquid semiconductor material can be produced as required in the reactor container by corresponding variation of the amount of particles of the semiconductor material and/or the precursor compound of the semiconductor material which is fed into the highly heated gas flow. In particular, in this case, coupling the transfer means to the reactor container in which the liquid semiconductor material is condensed out and/or separated from the gas flow can be effected, for example, by a siphon-like pipe connection. The resulting liquid semiconductor material accumulates in the reactor container and produces a corresponding hydrostatic pressure. Via the siphon-like pipe connection it is possible, in a manner governed by pressure, for liquid semiconductor material, in a controlled manner, to be discharged from the reactor container or fed to the melt, in which the transition of the liquid semiconductor material to the solid state with formation of monocrystalline crystal structures then takes place.

The method affords clear advantages over traditional techniques of obtaining monocrystalline semiconductor materials. From an energetic standpoint it is highly advantageous for semiconductor materials arising in liquid form to be converted directly into a monocrystalline form, without the detour via polycrystalline semiconductor material. Furthermore, the semiconductor material, owing to the greatly shortened method sequence, passes through only very few potential sources of contamination. Consequently, it is possible to produce semiconductor material with very high purity.

Further features will become apparent from the following description of a preferred installation for producing a monocrystalline semiconductor material in conjunction with the appended claims. In this case, individual features can respectively be realized by themselves or as a plurality in combination with one another. The preferred example described serves merely for elucidation and for a better understanding and should in no way be understood to be restrictive.

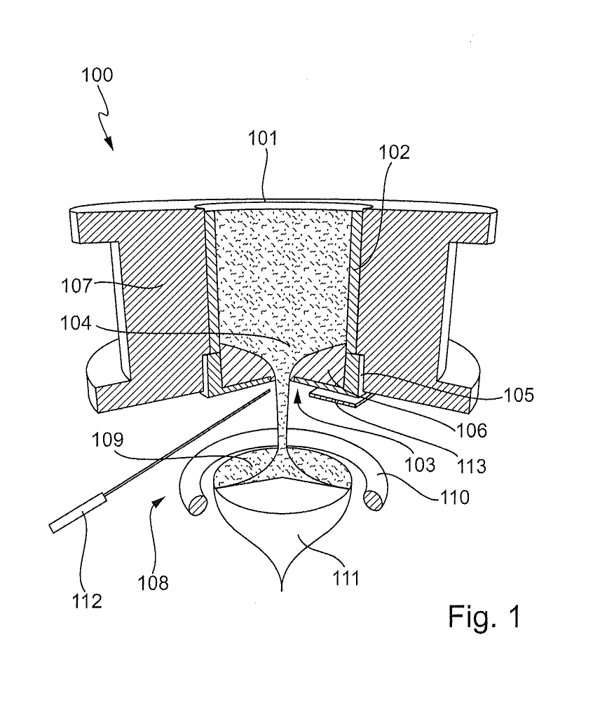

Turning now to FIG. 1 as a source of a liquid semiconductor material serving as starting material, installation 100 has a reactor container 101. The reactor container, illustrated in sectional view, comprises a cylindrical section that is laterally delimited by the reactor inner wall 102. The part of the reactor above the cylindrical section is not illustrated. It comprises, inter alia, an inlet for a silicon-containing plasma and also an outlet for gases to be discharged from the reactor. The plasma is generated from a carrier gas in a device disposed upstream of the reactor container 101 and is admixed with particles of the semiconductor material and/or a precursor compound of the semiconductor material. Below the cylindrical section, the interior of the reactor tapers towards the outlet 103, via which liquid semiconductor material 104 can exit from the reactor container 101. The configuration of this part of the interior of the reactor is given, in particular, by the L-shaped cooled wall/bottom elements 105 that are adjacent to the underside of the reactor inner wall 102. These are kept at a temperature below the melting point of the semiconductor material contained in the reactor container 101. The material correspondingly forms a solidified covering layer 106, which, if appropriate, can also extend over the outlet 103 and thus block the outlet. The reactor container 101 thus has a bottom region which at least partly consists of the semiconductor material to be produced. The reactor outer wall 107 is arranged around the reactor inner wall 102 and L-shaped cooled wall/bottom elements 105. The reactor outer wall can comprise heating, insulating and/or cooling media.

The heating zone 108 is arranged below the reactor container 101, a melt 109 composed of the semiconductor material being situated in the heating zone. The heating zone 108 comprises, as heating medium, the induction heating system 110, which is arranged around the melt 109 in a ring-shaped manner. For the melt, the seed crystal 111 serves as a substrate. It can be lowered together with the melt 109 from the heating zone 108 by suitable media, such that, at the lower end of the melt 109, a solidification front forms along which the semiconductor material crystallizes in the monocrystalline structure of the end cone 111.

The induction heating system 110 serves, in particular, to maintain the melt 109 in the heating zone 108. Furthermore, however, it also heats the bottom region of the reactor container 101. By turning on the laser 112, which is arranged as a medium for the controlled feeding of the liquid semiconductor material serving as starting material into the melt 109 in such a way that it can be focused onto the outlet 103, it is possible to melt semiconductor material blocking the outlet 103, if appropriate, such that the melt 109 can be fed with liquid semiconductor material in a controlled manner.

To prevent an uncontrolled discharge from the reactor container 101, the installation 100 comprises as a safeguard the blocker 113, which is a slide, with which the outlet 103 can be closed off The slide preferably consists of a material which cannot be heated or can scarcely be heated by high-frequency induction.

1. A method of producing a monocrystalline semiconductor material comprising:
providing a starting material composed of the semiconductor material,
transferring the starting material into a heating zone in which a melt composed of the semiconductor material is fed with the starting material, and
lowering the melt from the heating zone and/or raising the heating zone such that, at a lower end portion of the melt, a solidification front forms along which the semiconductor material crystallizes in a desired structure,
wherein the starting material composed of the semiconductor material is provided in liquid form and fed into the melt in liquid form.

2. The method according to claim 1, wherein, to provide the liquid starting material, particles of the semiconductor material and/or a precursor compound of the semiconductor material are fed into a gas flow, wherein the gas flow has sufficiently high temperature to convert the particles of the semiconductor material from a solid to a liquid and/or gaseous state and/or to thermally decompose the precursor compound.

3. The method according to claim 2, wherein the gas flow is conducted into a reactor container in which the liquid starting material is condensed and/or separated from the gas flow, and the liquid starting material is fed directly from the reactor container into the melt composed of the semiconductor material.

4. The method according to claim 3, wherein the reactor container is coated internally regions which contact the liquid semiconductor material, with a solid layer composed of the solidified semiconductor material.

5. The method according to claim 4, wherein thickness of the layer is monitored with a sensor and controlled by heating and/or cooling media.

6. The method according to claim 3, wherein the reactor has a solid bottom region which at least partly consists of the semiconductor material to be produced.

7. The method according to claim 6, wherein, to feed the liquid semiconductor material into the melt, the bottom region which at least partly consists of the semiconductor material to be produced is melted in a controlled manner.

8. The method according to claim 7, wherein the melting process is controlled by heating and/or cooling media arranged in the bottom region or are assigned thereto.

9. The method according to claim 8, wherein the heating and/or cooling media comprise at least one induction heating system and/or a focusable light beam and/or beam of matter.

10. An installation that produces a monocrystalline semiconductor material comprising:
a source of a liquid semiconductor material serving as starting material,
heating media that produce and/or maintain a melt composed of the semiconductor material, and
media for the controlled feeding of the liquid semiconductor material serving as starting material into the melt.

11. The installation according to claim 10, wherein the source comprises a reactor container and/or a collecting container in which the liquid semiconductor material serving as starting material is formed and/or collected.

12. The installation according to claim 10, wherein the means for the controlled feeding of the liquid semiconductor material serving as starting material into the melt comprise grooves and/or pipes, which at least partly consist of quartz, graphite and/or silicon nitride.

13. The installation according to claim 11, wherein the means for the controlled feeding of the liquid semiconductor material serving as starting material into the melt comprise grooves and/or pipes, which at least partly consist of quartz, graphite and/or silicon nitride.

14. The method according to claim 4, wherein the reactor has a solid bottom region which at least partly consists of the semiconductor material to be produced.

15. The method according to claim 5, wherein the reactor has a solid bottom region which at least partly consists of the semiconductor material to be produced.
